(19) United States
(12) Patent Application Publication
(10) Pub. No.: US 2024/0290733 A1
(43) Pub. Date: Aug. 29, 2024

(54) RADIO FREQUENCY SEMICONDUCTOR DEVICE AND METHOD FOR FABRICATING A RADIO FREQUENCY SEMICONDUCTOR DEVICE

(71) Applicant: Infineon Technologies AG, Neubiberg (DE)

(72) Inventors: Simon KORNPROBST, Stephanskirchen (DE); Tuncay ERDÖL, Unterhaching (DE); Walter HARTNER, Bad Abbach (DE)

(21) Appl. No.: 18/440,561

(22) Filed: Feb. 13, 2024

(30) Foreign Application Priority Data
Feb. 24, 2023 (EP) 23158383

(51) Int. Cl. H01L 23/66; H01L 23/498; H01L 23/552

(52) U.S. Cl. CPC H01L 23/66; H01L 23/49816; H01L 23/49822; H01L 23/552; H01L 2223/6605

(57) ABSTRACT

A radio frequency (RF) semiconductor device to process RF signals in an operating frequency range is provided which includes, a semiconductor chip including a first surface, a second surface opposite to the first surface and sidewalls, the semiconductor chip including an active chip area, a redistribution layer including a first side, the first side of the redistribution layer facing the first surface of the semiconductor chip, an RF absorption layer external to the active chip area, wherein the RF absorption layer includes a doped semiconductor material.

### CROSS-REFERENCE TO RELATED APPLICATION

This application claims priority to European Patent Application No. 23158383 filed on Feb. 24, 2023, the content of which is incorporated by reference herein in its entirety.

### TECHNICAL FIELD

The present disclosure relates to a radio frequency semiconductor device and in particular to a radio frequency semiconductor device with high loss material. In addition, the present disclosure relates to method of manufacturing such devices.

### BACKGROUND

In radio frequency (RF) semiconductor devices, elimination of undesired radiation is a crucial factor for reliable device performance. The undesirable radiation may originate from electrical interconnections of the RF semiconductor device or from external radiation sources.

The undesired radiation lowers the quality of an RF signal to be processed by the RF semiconductor device. The current paths in the device are impacted by undesired radiation, increasing the cross-communication between the different routes of the circuits and electromagnetic interference (EMI).

Mold compounds applied in the RF semiconductor device packaging usually exhibit low-loss properties such that the RF signal can propagate without significant attenuation. The RF signals may be reflected at the mold compound-air interface transferring energy back in the RF semiconductor device. This may cause failure or poor performance of the RF device.

Accordingly, it is an object of the present application to provide a concept for an RF semiconductor device in which impact of undesired radiation is reduced. This object is solved by a radio frequency semiconductor device according to claim 1 and a method of fabricating a radio frequency semiconductor device according to claim 14.

### SUMMARY

According to an example of the implementation, a radio frequency (RF) semiconductor device to process RF signals in an operating frequency range includes a semiconductor chip including a first surface, a second surface opposite to the first surface and sidewalls, wherein the semiconductor chip includes an active chip area. The RF semiconductor device includes a redistribution layer including a first side, the first side of the redistribution layer facing the first surface of the semiconductor chip. The RF semiconductor device further includes an RF absorption layer external to the active chip area, wherein the RF absorption layer includes a doped semiconductor material such that the dissipating factor of the RF absorption layer is equal or greater than 0.1 in the operating frequency range.

According to an example of the implementation a method for fabricating a radio frequency (RF) semiconductor device to process RF signals in an operating frequency range includes:
providing a semiconductor chip including a first surface, a second surface opposite to the first surface and sidewalls, the semiconductor chip including an active chip area;
providing a redistribution layer including a first side, the first side of the redistribution layer facing the first surface of the semiconductor chip;
disposing an RF absorption layer external to the active chip area, wherein the RF absorption layer includes a doped semiconductor material such that the dissipating factor of the RF absorption layer is equal or greater than 0.1 in the operating frequency range.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 schematically illustrate a cross-sectional view of a radio frequency (RF) semiconductor device.

FIG. 2 schematically illustrate a cross-sectional view of a RF semiconductor device.

FIG. 3 schematically illustrate a cross-sectional view of a RF semiconductor device.

FIG. 4 schematically illustrate a cross-sectional view of a RF semiconductor device.

FIG. 5 schematically illustrate a cross-sectional view of a RF semiconductor device.

FIG. 6 schematically illustrate a cross-sectional view of a RF semiconductor device.

FIG. 7 schematically illustrate a cross-sectional view of a RF semiconductor device.

FIG. 8 shows an experimental measurement of dielectric constant.

### DETAILED DESCRIPTION

In the following description, directional terminology, such as “top”, “bottom”, “upper”, “lower” “front”, “back” etc., is used with reference to the orientation of figures being described. The components of the disclosure can be positioned in a number of different orientations, the directional terminology is used for purposes of illustration and is in no way limiting.

Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements co-operate or interact with each other regardless of whether they are in direct physical or electrical contact, or they are not in direct contact with each other; intervening elements or layers may be provided between the “bonded”, “attached”, or “connected” elements.

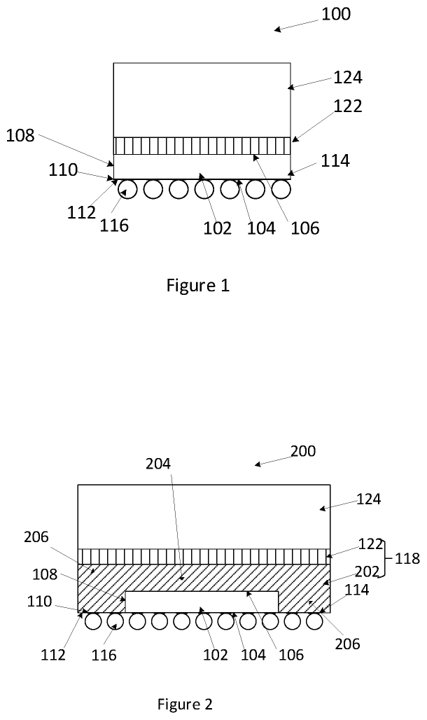

FIG. 1 shows a cross sectional view of a radio frequency (RF) semiconductor device 100. The RF semiconductor device 100 has a semiconductor chip 102 operating in a predetermined frequency range such as a millimeter-wave frequency range, for example in a first frequency range from 40 GHz to 500 GHz or in a second frequency range from 50 GHz to 250 GHz. In some examples, the semiconductor chip 102 may correspond to a radar chip and may be used as a transmitter, a receiver, a sensor, a detector etc. In other examples the semiconductor chip 102 may be a 5G or 6G communication chip, a high data transfer communication system, wireless backhaul systems of body scanning systems for security.

The semiconductor chip 102 has a first surface 104, a second surface 106 opposite to the first surface 104 and sidewalls 108. The first surface 104 and the second surface 106 may be referred to as a first main surface and second main surface. An active chip area having transistors and other circuit elements is provided in the semiconductor chip 102. The active chip area may be capable of generating RF signals, processing RF signals, and analyzing RF signals and other signals.

The first surface 104 of the semiconductor chip 102 is arranged on a first side 114 of a redistribution layer 110 and an electrical contact is established between the semiconductor chip 102 and electrically conductive structures of the redistribution layer. For example, the electrical contact may be formed by a bond pad which may be made of aluminum and/or copper. This allows an RF signal to be transmitted from the semiconductor chip 102 to the electrical contacts and/or vice-versa. In the implementation of FIG. 1, the RF semiconductor device 100 may correspond to a wafer level package.

The redistribution layer 110 may have one or more electrically conductive structures in form of metal lines or metal planes, running parallel to the first surface 104 of the semiconductor chip 102. The electrically conductive structures route the electric current in the RF semiconductor device 100 and are electrically isolated from each other by a dielectric material. The conductive structures may be made of aluminum, copper or a copper alloy. The dielectric material may comprise an oxide or a nitride.

The redistribution layer 110 has a second side 112 opposite to the first side 114. A plurality of solder balls 116 is arranged on the second side 112 of the redistribution layer 110. Accordingly, the redistribution layer 110 establishes the electrical connection between the solder balls 116 and the semiconductor chip 102. A printed circuit board (PCB) which is not shown in FIG. 1 may be electrically and mechanically mounted to the solder balls 116. The solder balls 116 may comprise at least one of Sn, Ag, or Cu. The solder balls 116 may have diameters in a range between 200 and 400 μm and pitches in a range between of 400 and 600 μm. In some examples, Flip-Chip BGAs (Ball Grid Arrays) or Wirebond-BGA may be used for establishing the electrical and mechanical connection to the PCB.

An RF absorption layer 122 is arranged external to the active chip area, such that the RF absorption layer 122 covers and is in contact with the second surface 106 of the semiconductor chip 102. The RF absorption layer 122 can be considered as part of the package for the semiconductor chip 102. The RF absorption layer 122 comprises a doped semiconductor material having (i) an electrical resistivity in a range of 1-100 ohm-cm (ii) a real part of a dielectric constant in a range of 5-15 (iii) a dissipation factor or loss tangent greater than or equal to 0.1, in the operating frequency range. The dissipation factor (D_{f}) or loss tangent (tan(δ)) of the RF absorption layer 122 is defined as

$${D}_{f} = tan ( δ ) = \frac{ω {ε}_{0} {ε}_{r}^{″} + σ}{ω {ε}_{0} {ε}_{r}^{′}}$$

Where, ω is the angular frequency, σ is the electrical conductivity, ε₀ is the vacuum permittivity, εᵣ′ is the real part of relative permittivity of the RF absorption layer 122 and εᵣ″ is the imaginary part of relative permittivity of the RF absorption layer 122. The real part of the relative permittivity (εᵣ′) of the RF absorption layer 122 is also referred as Dₖ.

In some examples, the RF absorption layer 122 may comprise a doped semiconductor filler material wherein the doped semiconductor filler material further comprises doped semiconductor particles. In some examples, the semiconductor may be silicon and the dopant may be a p-dopant such as boron. A particle size of the doped semiconductor particles in the semiconductor filler material may be less than 100 μm. In some examples, the maximum dimension in all space directions of each of the particles is less than 100 μm. In some examples, a mean value of the maximum dimension of each particle is less than 100 μm. The semiconductor particles comprise at least one of p-doped crystal semiconductor particles, p-doped amorphous semiconductor particles or p-doped semiconductor oxide particles. A shape of the semiconductor particle may be spherical or of any other regular or irregular shape. The RF absorption layer 122 comprises the doped semiconductor filler material with a volume of at least 45% of the total RF absorption layer 122 volume and a polymer mold material with a volume of 55% or less of the total RF absorption layer 122 volume. The mold materials may be thermoset polymers, thermoplastic polymers or elastomer polymers.

A metal plate 124 may be attached to the RF absorption layer 122 on a side opposite to a side facing the redistribution layer 110. The metal plate 124 allows an efficient heat removal from the semiconductor chip 102 via the second surface 106.

With the introduction of the RF absorption layer 122 into a semiconductor package which uses doped semiconductor material to achieve an absorption of radiation, a new concept is introduced which allows an efficient, cost effective and configurable absorption concept for packaged RF semiconductor devices. In particular, with a proper selection the doping material, the doping concentration, or the volume of the semiconductor material within the layer, the RF absorption layer 122 can be tailored in a flexible manner as a high loss layer such that the dissipating factor of the RF absorption layer 122 is equal or greater than 0.1 in the operating frequency range. The new concept is therefore inexpensive and highly flexible since an adaption of the absorption properties can be achieved by varying one of the above-mentioned properties of the semiconductor material. This makes the concept especially suitable for upcoming technologies and the semiconductor chip 102 scaling in which more and more functionalities are integrated since the absorption can be easily varied and adapted for example in order to take into account the required operation frequency, the size or design of the RF semiconductor device 100, the routing of RF lines within the RF semiconductor device 100 or the package type used. The concept can be used for single-chip RF devices or multi-chip RF devices in which multiple semiconductor chips are arranged above or lateral to each other within a semiconductor package.

The new concept thereby allows improving an electrical performance of the RF semiconductor device 100, for example by reducing channel-to-channel isolation and improving the robustness of the RF semiconductor device 100 with respect to reflecting materials or signal sources in the surrounding.

Furthermore, the new concept is well-suited for packages in which a metal plate 124 is arranged for heat removal as described above. By providing the above described RF absorption layer 122, reflections from the metal plate 124 back into the semiconductor chip 102 can be significantly reduced allowing a significant improvement of the performance even under such conditions.

Using the doped semiconductor material as a filler material in a polymer mold material as described above allows using molding techniques in order to manufacture the RF absorption layer 122. This enables the provision of the RF absorption layer 122 in any shape. While the RF absorption layer 122 is shown in the FIG. 1 in a planar shape it is to be understood that other shapes can be easily manufactured using molding techniques.

The new concept is further well-suited for fan-out packages where the RF signals are in the fan-out area significantly influenced by the dielectric properties of the mold material and a need exists to obtain low-loss properties of the semiconductor package in this area so that the RF signals are allowed to propagate without significant attenuation. The described concept allows therefore to provide low loss mold material in areas of signal propagation and the RF absorption layer 122 as a high loss material in areas where radiation absorption is advantageous as will be described with respect to FIG. 2.

FIG. 2 shows an example of an RF semiconductor device 200 which may include some or all features of the RF semiconductor device 100 of FIG. 1. The RF semiconductor device 200 additionally comprises a chip package 118. A part of the semiconductor chip 102 and a part of the first side 114 of the redistribution layer 110 is encapsulated by the chip package 118. The redistribution layer 110 may at least partially extend over the first surface 104 of the semiconductor chip 102 such that the semiconductor chip 102 has a smaller surface area than the redistribution layer 110. The area of the redistribution layer 110 not covered by the semiconductor chip 102 is also referred as a fan-out area. The RF semiconductor device 200 may be referred as a fan-out device or a fan-out package. The fan-out package may be manufactured for example by an eWLB (embedded Wafer Level Ball Grid Array) process.

The chip package 118 in addition to the RF absorption layer 122, has an encapsulation material 202.

The dissipation factor or loss tangent of the encapsulation material 202 is less than 0.1, such that the encapsulation material 202 is a low-loss material in the operating frequency range. The low-loss properties of the encapsulation material 202 decreases the attenuation of the RF signal to be processed by the RF semiconductor device 200 in the fan-out area. The encapsulation material 202 may be epoxy, filled epoxy, glass fiber filled epoxy, thermoset polymers, thermoplastic polymers, or elastomer polymers,

In the RF semiconductor device 200, the chip package 118 encapsulates the semiconductor chip 102 and parts of the redistribution layer 110. In particular, the encapsulation material 202 is arranged between the RF absorption layer 122 and the first side 114 of the redistribution layer 110. The encapsulation material 202 covers and is in contact with the sidewalls 108 and second surface 106 of the semiconductor chip 102 and the parts of the first side 114 of the redistribution layer 110. As described above, a metal plate 124 is attached to the chip package 118 on a side opposite to a side facing the redistribution layer 110.

In some examples the RF semiconductor device 200 can be manufactured using a multi-mold process. In a first molding step, the low-loss encapsulation material 202 is formed. In a second molding step following the first molding step, the RF absorption layer 122 is formed for example directly on the low-loss encapsulation material 122.

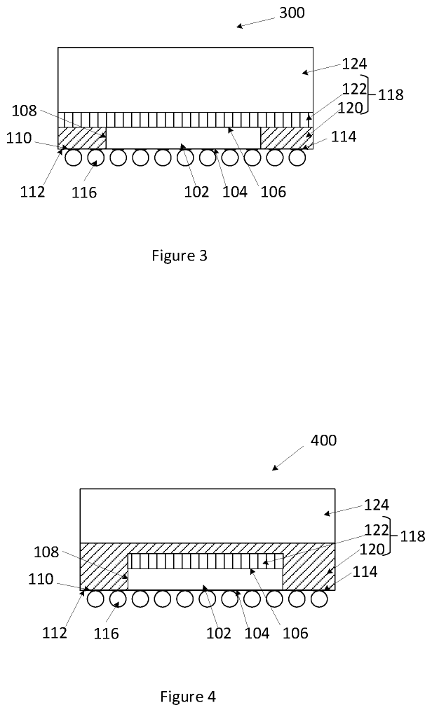

FIG. 3 shows an RF semiconductor device 300 which may include some or all features of the RF semiconductor device 200 of FIG. 2. The RF absorption layer 122 covers and is in contact with the second surface 106 of the semiconductor chip 102. The RF absorption layer 122 extends beyond the second surface 106 of the semiconductor chip 102.

The encapsulation material 202 is filled between the RF absorption layer 122 and the redistribution layer 110 such that the encapsulation material 202 covers and is in contact with the sidewalls 108 of the semiconductor chip 102, the parts of the first side 114 of the redistribution layer 110. In other words, in a first area 204, the semiconductor chip 102 is between the RF absorption layer 122 and the redistribution layer 110 while, in a second area 206, the encapsulation material 202 is between the RF absorption layer 122 and the redistribution layer 110. In some examples the second area corresponds to the fan-out area.

FIG. 4 shows an RF semiconductor device 400 which may include some or all features of the RF semiconductor device 200 of FIG. 2. The RF absorption layer 122 covers and is in contact with the second surface 106 of the semiconductor chip 102. The encapsulation material 202 covers and is in contact with the sidewalls 108 of the semiconductor chip 102, the parts of the first side 114 of the redistribution layer 110 and the RF absorption layer 122 covering the second surface 106 of the semiconductor chip 102. A material layer between the RF absorption layer 122 and the second surface 106 of the semiconductor chip may be applied as an adhesion layer.

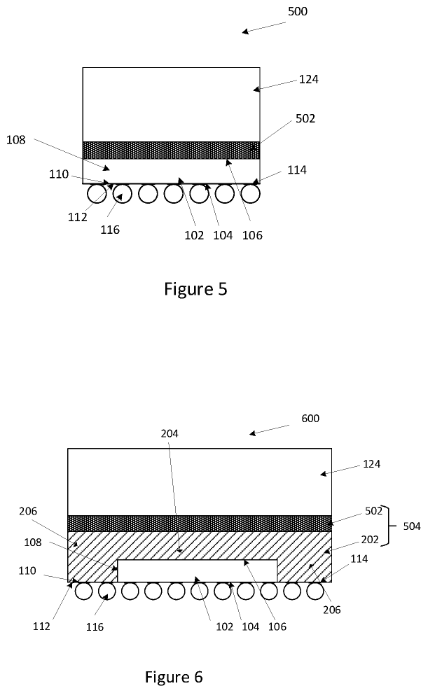

FIG. 5 shows an RF semiconductor device 500 which may include some or all features of the RF semiconductor device 100 of FIG. 1. In FIG. 5, the RF absorption layer 502 is a doped semiconductor layer such as a bulk semiconductor layer. In an example, the RF absorption layer 502 is a p-doped silicon layer having (i) an electrical resistivity in a range of 1-100 ohm-cm (ii) a real part of a dielectric constant in a range of 5-15 (iii) a dissipation factor or loss tangent greater than or equal to 0.1, in the operating frequency range.

Similar to FIG. 1, the RF absorption layer 502 shown in FIG. 5 is disposed on the second surface 106 of the semiconductor chip 102 and a metal plate 124 is provided on the RF absorption layer 502.

FIG. 6 shows a RF semiconductor device 600 which may include some or all features of the RF semiconductor device 500 of FIG. 2 or FIG. 5. The RF semiconductor device 600 comprises a chip package 504. The chip package 504 encapsulates the semiconductor chip 102 and parts of the redistribution layer 110. In particular, the encapsulation material 202 is arranged between the RF absorption layer 502 and the first side 114 of the redistribution layer 110. The encapsulation material 202 covers and is in contact with the sidewalls 108 and second surface 106 of the semiconductor chip 102 and the parts of the first side 114 of the redistribution layer 110. Similar to FIG. 5, the RF absorption layer 502 is a doped bulk semiconductor layer.

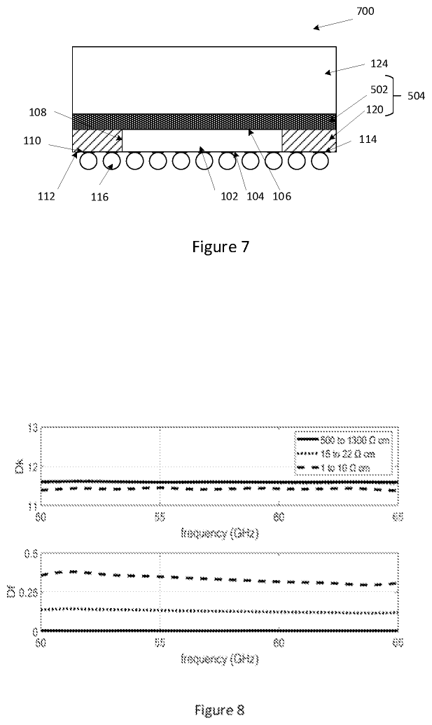

FIG. 7 shows a RF semiconductor device 700 which may include some or all features of the RF semiconductor device 600 of FIG. 3 or FIG. 6. The RF absorption layer 502 covers and is in contact with the second surface 106 of the semiconductor chip 102. The RF absorption layer 502 extends beyond the second surface 106 of the semiconductor chip 102. The encapsulation material 202 is filled between the RF absorption layer 502 and the redistribution layer 110 such that the encapsulation material 202 covers and is in contact with the sidewalls 108 of the semiconductor chip 102, the parts of the first side 114 of the redistribution layer 110.

In the above-described examples, RF absorption layers 122 and 502 have been described utilizing doped semiconductor material as semiconductor packaging material to allow in-package absorption of radiation. The RF absorption layers 122 and 502 comprise doped semiconductor as filler material particles or as a semiconductor layer formed as one piece of semiconductor material. The proposed concept allows the tuning of RF properties to achieve a high-loss at mm-wave frequencies. Various parameters such as resistivity, doping type and crystal orientation may be taken into account to tune the RF absorption layer 122 and 502 to obtain the desired loss properties. Investigations have been made for doped silicon in various configurations. Results thereof will be discussed with respect to FIG. 8.

FIG. 8 shows a real part of the relative permittivity (Dₖ) and dissipation factor (D_{f}) or loss tangent (tan(δ)) of the dielectric constant for silicon material of different resistivities range of 1-10 ohm-cm, 15-22 ohm-cm and 500 to 1300 ohm-cm having a 100 crystal orientation and p-type boron-doping. FIG. 8 shows the values between 50 GHz and 65 GHz.

As previously described, dissipation factor (D_{f}) or loss tangent (tan(δ)) of the RF absorption layer 122, 502 is defined as

$${D}_{f} = tan ( δ ) = \frac{ω {ε}_{0} {ε}_{r}^{″} + σ}{ω {ε}_{0} {ε}_{r}^{′}}$$

Where, ω is the angular frequency, σ is the electrical conductivity, ε₀ is the vacuum permittivity, εᵣ′ is the real part of relative permittivity of the RF absorption layer 122 and 502 and εᵣ″ is the imaginary part of relative permittivity of the RF absorption layer 122 and 502. The real part of the relative permittivity (εᵣ′) of the RF absorption layer 122 and 502 is also referred as Dₖ.

It can be noted that the higher the value of D_{f} and the lower the value of Dₖ, the higher the dissipation factor.

In general, the dielectric properties of different p-doped Si show a low frequency dependency in the addressed frequency range at mm-Wave frequencies. As can be seen from FIG. 8, the Dₖ values for different doping levels between 1 ohm-cm up to 1300 ohm-cm are all between in the range between 11 and 12. At the same time, the dissipation factor D_{f} is strongly influenced by the doping level which tunes the conductivity of the RF absorption layer. While a resistivity value between 500 and 1300 ohm-cm results in a very low loss material in the given frequency range, and the behavior is very similar to undoped silicon, an increasing doping level decreases the resistivity of the RF absorption layer and therefore high absorption can be achieved. For example, a resistivity value of 1 to 10 ohm-cm equals to a dissipation factor D_{f} of approximately 0.3 with the given characterization results.

Increasing the real-part of a relative permittivity Dₖ value lowers the dissipation factor D_{f} for a given resistivity of the RF absorption layer. Table 1 below shows a number of values of dissipation factor D_{f} for specific resistivity values and real-part of a relative permittivity Dₖ values. In general, any combination of Dₖ values and resistivity values which achieves a dissipation factor D_{f} to be greater than 0.1 can be considered as a high-loss material for the RF absorption layer.

TABLE 1

| | Dk = 8 | Dk = 11.5 | Dk = 15 |
|---|---|---|---|
| 0.1 ohm-cm | 37.45 | 26.05 | 19.97 |
| 1 ohm-cm | 3.74 | 2.61 | 2 |
| 10 ohm-cm | 0.37 | 0.26 | 0.2 |
| 15 ohm-cm | 0.25 | 0.17 | 0.13 |
| 22 ohm-cm | 0.17 | 0.12 | 0.09 |
| 500 ohm-cm | 0.01 | 0.01 | 0 |
| 1300 ohm-cm | 0 | 0 | 0 |

In general, resistivities from 1 to 100 ohm-cm have been shown to obtain high loss behavior. Furthermore, the crystal orientation is an aspect having an impact on the loss behavior. In FIG. 8 the dielectric properties are shown for a 100 crystal orientation and an incident field perpendicular to the sample which can be considered as a doped wafer with a thickness less than 1 mm. In reality however, RF signals will propagate at different angles through the material. Differences of the dielectric properties between 100 and 111 orientations have been observed with the loss for the example of FIG. 8 being even higher for the 111 crystal orientation compared to the 100 crystal orientation.

### ASPECTS

The following aspects pertain to further aspects of the disclosure:

Aspect 1 discloses a radio frequency (RF) semiconductor device to process RF signals in an operating frequency range comprising, a semiconductor chip comprising a first surface, a second surface opposite to the first surface and sidewalls, the semiconductor chip comprising an active chip area, a redistribution layer comprising a first side, the first side of the redistribution layer facing the first surface of the semiconductor chip, an RF absorption layer external to the active chip area, wherein the RF absorption layer comprises a doped semiconductor material such that the dissipating factor of the RF absorption layer is equal or greater than 0.1 in the operating frequency range.

Aspect 2 discloses the RF semiconductor device according to Aspect 1, wherein the RF absorption layer is disposed on the semiconductor chip outside of the active chip area.

Aspect 3 discloses the RF semiconductor device according to Aspect 1, further comprising a chip package disposed over the second surface of the semiconductor chip, wherein the chip package comprises the RF absorption layer.

Aspect 4 discloses the RF semiconductor device according to Aspect 3, wherein the chip package comprises in addition to the RF absorption layer an encapsulation material, wherein sidewalls of the semiconductor chip and a part of the first side of the redistribution layer are encapsulated by the encapsulation material, wherein the encapsulation material comprises a dissipating factor of less than 0.1 in the operating frequency range.

Aspect 5 discloses the RF semiconductor device according to Aspect 1, wherein a plurality of solder balls is arranged on a second side of the redistribution layer opposite to the first side to mechanically and electrically connect the RF device to a printed circuit board.

Aspect 6 discloses the RF semiconductor device according to Aspect 1, wherein the RF absorption layer comprises a doped semiconductor filler material with a volume of at least 45%.

Aspect 7 discloses the RF semiconductor device according to Aspect 6, wherein the RF absorption layer comprises a polymer mold material with a volume of 55% or less.

Aspect 8 discloses the RF semiconductor device according to Aspect 6, wherein the doped semiconductor filler material comprises doped semiconductor particles, wherein the semiconductor filler material comprises: a particle size of the doped semiconductor particle is less than 100 μm, wherein the semiconductor particles comprise at least one of p-doped crystal semiconductor particles, p-doped amorphous semiconductor particles or p-doped semiconductor oxide particles; an electrical resistivity in a range of 1 to 100 ohm-cm; and a real part of a dielectric constant is in range of 5 to 15.

Aspect 9 discloses the RF semiconductor device according to Aspect 1, wherein the RF absorption layer comprises: a p-doped silicon layer, wherein an electrical resistivity of the p-doped layer is in range of 1 to 100 ohm cm; and a real-part of a dielectric constant is in a range of 5 to 15.

Aspect 10 discloses the RF semiconductor device according to Aspects 1 to 9, wherein an encapsulation material is arranged between the RF absorption layer and the first side of the redistribution layer, wherein the encapsulation material covers and is in contact with the sidewalls and second surface of the semiconductor chip and the first side of the redistribution layer.

Aspect 11 discloses the RF semiconductor device according to Aspects 1 to 9, wherein the encapsulation material covers and is in contact with the side walls of the semiconductor chip and the first side of the redistribution layer, wherein the RF absorption layer covers and is in contact with the second surface of the semiconductor chip and the encapsulation material covering the first side of the redistribution layer.

Aspect 12 discloses the RF semiconductor device according to Aspects 1 to 9, wherein the RF absorption layer covers and is in contact with the second surface of the semiconductor chip, wherein the encapsulation material covers and is in contact with the sidewalls of the semiconductor chip, the first side of the redistribution layer and the RF absorption layer covering the second surface of the semiconductor chip.

Aspect 13 discloses the RF semiconductor device according to Aspect 1, wherein a metal plate is attached to the chip package, at chip package-air interface lateral to the second surface of the semiconductor chip.

Aspect 14 discloses a method for fabricating a radio frequency (RF) semiconductor device to process RF signals in an operating frequency range comprises: providing a semiconductor chip comprising a first surface, a second surface opposite to the first surface and sidewalls, the semiconductor chip comprising an active chip area; providing a redistribution layer comprising a first side, the first side of the redistribution layer facing the first surface of the semiconductor chip; disposing an RF absorption layer external to the active chip area, wherein the RF absorption layer comprises a doped semiconductor material such that the dissipating factor of the RF absorption layer is equal or greater than 0.1 in the operating frequency range.

1. A radio frequency (RF) semiconductor device to process RF signals in an operating frequency range comprising:
a semiconductor chip comprising a first surface, a second surface opposite to the first surface, sidewalls, and an active chip area;
a redistribution layer comprising a first side, the first side of the redistribution layer facing the first surface of the semiconductor chip; and
an RF absorption layer external to the active chip area, wherein the RF absorption layer comprises a doped semiconductor material such that a dissipating factor of the RF absorption layer is equal to or greater than 0.1 in an operating frequency range.

2. The RF semiconductor device according to claim 1, wherein the RF absorption layer is disposed on the semiconductor chip outside of the active chip area.

3. The RF semiconductor device according to claim 1, further comprising:
a chip package disposed over the second surface of the semiconductor chip, wherein the chip package comprises the RF absorption layer.

4. The RF semiconductor device of claim 3, wherein the chip package further comprises:
an encapsulation material,
wherein the sidewalls of the semiconductor chip and a part of the first side of the redistribution layer are encapsulated by the encapsulation material, and
wherein the encapsulation material comprises a dissipating factor of less than 0.1 in the operating frequency range.

5. The RF semiconductor device according to claim 1, wherein a plurality of solder balls is arranged on a second side of the redistribution layer opposite to the first side to mechanically and electrically connect the RF semiconductor device to a printed circuit board.

6. The RF semiconductor device according to claim 1, wherein the RF absorption layer comprises a doped semiconductor filler material with a volume of at least 45%.

7. The RF semiconductor device according to claim 6, wherein the RF absorption layer comprises a polymer mold material with a volume of 55% or less.

8. The RF semiconductor device according to claim 6, wherein the doped semiconductor filler material comprises doped semiconductor particles, and wherein the semiconductor filler material comprises:
a particle size of the doped semiconductor particles is less than 100 μm, wherein the doped semiconductor particles comprise at least one of p-doped crystal semiconductor particles, p-doped amorphous semiconductor particles, or p-doped semiconductor oxide particles;
an electrical resistivity in a range of 1 to 100 ohm-cm; and
a real part of a relative permittivity is in range of 5 to 15.

9. The RF semiconductor device according to claim 1, wherein the RF absorption layer comprises:
a p-doped silicon layer, wherein an electrical resistivity of the p-doped silicon layer is in range of 1 to 100 ohm cm; and
a real-part of a relative permittivity is in a range of 5 to 15.

10. The RF semiconductor device according to claim 1, wherein an encapsulation material is arranged between the RF absorption layer and the first side of the redistribution layer, and
wherein the encapsulation material covers and is in contact with the sidewalls and the second surface of the semiconductor chip and the first side of the redistribution layer.

11. The RF semiconductor device according to claim 4, wherein the encapsulation material covers and is in contact with the sidewalls of the semiconductor chip and the first side of the redistribution layer, and
wherein the RF absorption layer covers and is in contact with the second surface of the semiconductor chip and the encapsulation material covering the first side of the redistribution layer.

12. The RF semiconductor device according to claim 1, wherein the RF absorption layer covers and is in contact with the second surface of the semiconductor chip, and
wherein the encapsulation material covers and is in contact with the sidewalls of the semiconductor chip, the first side of the redistribution layer and the RF absorption layer covering the second surface of the semiconductor chip.

13. The RF semiconductor device according to claim 3, wherein a metal plate is attached to the chip package at a chip package air interface that is lateral to the second surface of the semiconductor chip.

14. A method for fabricating a radio frequency (RF) semiconductor device to process RF signals in an operating frequency range comprises:
providing a semiconductor chip comprising a first surface, a second surface opposite to the first surface, sidewalls, and an active chip area;
providing a redistribution layer comprising a first side, the first side of the redistribution layer facing the first surface of the semiconductor chip; and
disposing an RF absorption layer external to the active chip area, wherein the RF absorption layer comprises a doped semiconductor material such that a dissipating factor of the RF absorption layer is equal to or greater than 0.1 in an operating frequency range.

15. The method according to claim 14, wherein the RF absorption layer is disposed on the semiconductor chip outside of the active chip area.

16. The method according to claim 14, further comprising:
disposing a chip package over the second surface of the semiconductor chip, wherein the chip package comprises the RF absorption layer.

17. The method according to claim 16, further comprising:
encapsulating the sidewalls of the semiconductor chip and a part of the first side of the redistribution layer with an encapsulation material,
wherein the encapsulation material comprises a dissipating factor of less than 0.1 in the operating frequency range.

18. The method according to claim 14, wherein a plurality of solder balls is arranged on a second side of the redistribution layer opposite to the first side to mechanically and electrically connect the RF semiconductor device to a printed circuit board.

19. The method according to claim 14, wherein the RF absorption layer comprises a doped semiconductor filler material with a volume of at least 45%.

20. The method according to claim 19, wherein the RF absorption layer comprises a polymer mold material with a volume of 55% or less.
